(19) United States
(12) Patent Application Publication
(10) Pub. No.: US 2026/0206285 A1
(43) Pub. Date: Jul. 16, 2026

(54) SEMICONDUCTOR DEVICE

(71) Applicant: Mitsubishi Electric Corporation, Tokyo (JP)

(72) Inventors: Takamasa MIYAZAKI, Tokyo (JP); Akinori SUMI, Tokyo (JP); Kazuhiro KAWAHARA, Tokyo (JP); Seiya SUGIMACHI, Tokyo (JP); Kazuki NISHIDA, Tokyo (JP)

(73) Assignee: Mitsubishi Electric Corporation, Tokyo (JP)

(21) Appl. No.: 19/269,941

(22) Filed: Jul. 15, 2025

(30) Foreign Application Priority Data
Jan. 10, 2025 (JP) 2025-004046

(51) Int. Cl. H10D 80/20; H01L 23/00; H01L 23/31; H01L 23/495

(52) U.S. Cl. CPC H10D 80/20; H10W 70/411; H10W 70/461; H10W 70/481; H10W 74/111; H10W 90/811; H10W 90/753; H10W 90/754

(57) ABSTRACT

A semiconductor device includes: a switching device; a control semiconductor device controlling the switching device; a capacitance adjustment unit including a capacitor and a conductor; and a molding resin encapsulating the switching device, the control semiconductor device and the capacitance adjustment unit, wherein the control semiconductor device includes a protection circuit outputting an error signal when an abnormality of the semiconductor device is detected, the protection circuit is connected to the capacitor via the conductor and charges the capacitor while the error signal is output, when voltage of the charged capacitor exceeds a threshold, the protection circuit stops the output of the error signal and discharges the capacitor, an opening is formed in the molding resin, and the conductor of the capacitance adjustment unit is exposed from the molding resin through the opening.

### BACKGROUND OF THE INVENTION

### Field

The present disclosure relates to a semiconductor device.

### BACKGROUND

In a semiconductor device in which switching devices, control semiconductor devices that control the switching devices, and the like are encapsulated by a molding resin, an output period of an error signal can be adjusted by adjusting the capacitance of a protection circuit that outputs the error signal. However, when a capacitor is provided outside the device, the area of the periphery of the device is increased. On the other hand, when a capacitor is built-in inside the device, a capacitance value of the capacitor cannot be externally adjusted. In contrast, there has been proposed a semiconductor device in which an opening is formed in a molding resin to expose a part of a terminal of a lead frame (for example, see Patent Literature 1). A chip capacitor is housed in the opening and one end of the chip capacitor is connected to the exposed terminal, so that the capacitance can be externally adjusted.

### CITATION LIST

### Patent Literature

Patent Literature 1: JP 2021-190522 A

### SUMMARY

However, in a conventional semiconductor device, it is necessary to draw out the other end of the chip capacitor to the outside, which leads to an increase in the number of external terminals of the semiconductor device.

The present disclosure has been made in order to solve the above-described problem, and an object thereof is to obtain a semiconductor device that can externally adjust an output period of an error signal without increasing the number of external terminals.

### Solution to Problem

A semiconductor device according to the present disclosure includes: a switching device; a control semiconductor device controlling the switching device; a capacitance adjustment unit including a capacitor and a conductor; and a molding resin encapsulating the switching device, the control semiconductor device and the capacitance adjustment unit, wherein the control semiconductor device includes a protection circuit outputting an error signal when an abnormality of the semiconductor device is detected, the protection circuit is connected to the capacitor via the conductor and charges the capacitor while the error signal is output, when voltage of the charged capacitor exceeds a threshold, the protection circuit stops the output of the error signal and discharges the capacitor, an opening is formed in the molding resin, and the conductor of the capacitance adjustment unit is exposed from the molding resin through the opening.

### Advantageous Effects of Invention

In the present disclosure, the capacitance value of the capacitance connected to the protection circuit can be adjusted depending on whether the conductor exposed from the molding resin is cut from the outside. In addition, it is not necessary to house the capacitor in the opening of the molding resin, which does not lead to an increase in the number of external terminals. As a result, the output period of the error signal can be externally adjusted without increasing the number of external terminals.

### BRIEF DESCRIPTION OF DRAWINGS

FIG. 1 is a plan view illustrating a semiconductor device according to a first embodiment.

FIG. 2 is a circuit diagram illustrating the semiconductor device according to the first embodiment.

FIG. 3 is a circuit diagram illustrating a protection circuit of the second control semiconductor device according to the first embodiment.

FIG. 4 is a top view illustrating the capacitance adjustment unit according to the first embodiment.

FIG. 5 is a top view illustrating the capacitance adjustment unit according to the first embodiment.

FIG. 6 is a cross-sectional view illustrating the capacitance adjustment unit according to the first embodiment.

FIG. 7 is a plan view illustrating a semiconductor device according to a second embodiment.

FIG. 8 is a circuit diagram illustrating a protection circuit of the second control semiconductor device according to the second embodiment.

FIG. 9 is a top view illustrating the capacitance adjustment unit according to the second embodiment.

FIG. 10 is a cross-sectional view illustrating the capacitance adjustment unit according to the second embodiment.

FIG. 11 is a plan view illustrating a semiconductor device according to a third embodiment.

FIG. 12 is a circuit diagram illustrating a protection circuit of the second control semiconductor device according to the third embodiment.

FIG. 13 is a top view illustrating the capacitance adjustment unit according to the third embodiment.

FIG. 14 is a plan view illustrating a semiconductor device according to a fourth embodiment.

FIG. 15 is a cross-sectional view illustrating the capacitance adjustment unit according to the fourth embodiment.

FIG. 16 is a plan view illustrating a semiconductor device according to a fifth embodiment.

### DESCRIPTION OF EMBODIMENTS

A semiconductor device according to the embodiments of the present disclosure will be described with reference to the drawings. The same components will be denoted by the same symbols, and the repeated description thereof may be omitted.

### First Embodiment

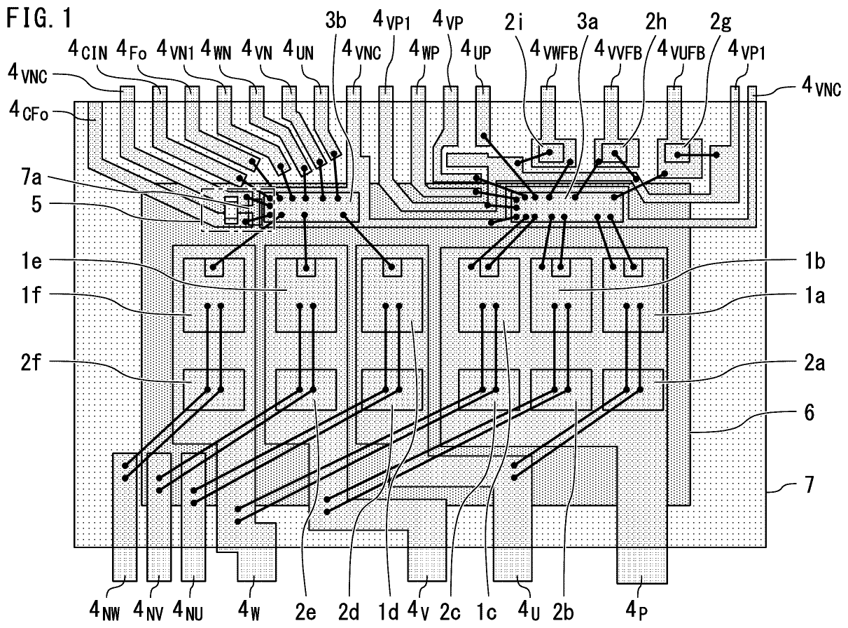

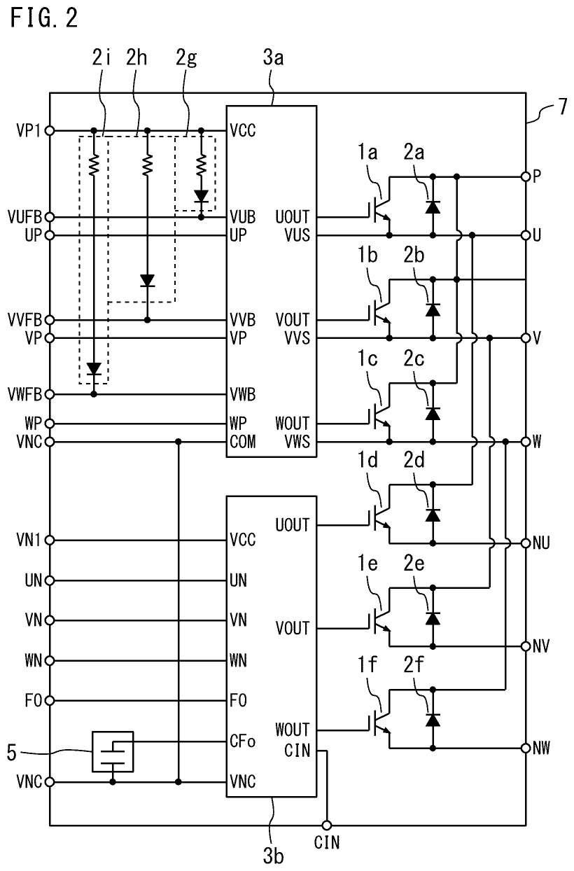

FIG. 1 is a plan view illustrating a semiconductor device according to a first embodiment. FIG. 2 is a circuit diagram illustrating the semiconductor device according to the first embodiment. The semiconductor device is an intelligent power module (IPM) obtained by modularizing switching devices 1a to 1f, diodes 2a to 2f, and first and second control semiconductor devices 3a and 3b into one electronic component. The switching devices 1a to 1f and the diodes 2a to 2f are included in an inverter that converts a DC voltage into a three-phase AC voltage.

The switching devices 1a, 1b, and 1c constitute an upper arm of the three-phase inverter. The switching devices 1d, 1e, and 1f constitute a lower arm of the three-phase inverter. The switching devices 1a to 1f is, for example, an insulated-gate bipolar transistor (IGBT), and alternatively, may be a field-effect transistor. The diodes 2a to 2f are freewheel diodes connected in antiparallel to the switching devices 1a to 1f, respectively. The first control semiconductor device 3a is a high voltage integrated circuit (HVIC) that controls the switching devices 1a, 1b, and 1c. The second control semiconductor device 3b is a low voltage integrated circuit (LVIC) that controls the switching devices 1d, 1e, and 1f.

Lead terminals 4_{P}, 4_{U}, 4_{V}, 4_{W}, 4_{NU}, 4_{NV}, 4_{NW}, 4_{VNC}, 4_{VP1}, 4_{VUFB}, 4_{UP}, 4_{VVFB}, 4_{VP}, 4_{VWFB}, 4_{WP}, 4_{VN1}, 4_{CFo}, 4_{UN}, 4_{VN}, 4_{WN}, 4_{Fo}, and 4_{CIN} are included in a lead frame.

The switching devices 1a, 1b, and 1c and the diodes 2a, 2b, and 2c are mounted on a die pad portion of the lead terminal 4_{P}. Collectors of the switching devices 1a, 1b, and 1c and cathodes of the diodes 2a, 2b, and 2c are connected to the lead terminal 4_{P}. The switching device 1d and the diode 2d are mounted on a die pad portion of the lead terminal 4_{U}. A collector of the switching device 1d and a cathode of the diode 2d are connected to the lead terminal 4_{U}. The switching device 1e and the diode 2e are mounted on a die pad portion of the lead terminal 4_{V}. A collector of the switching device 1e and a cathode of the diode 2e are connected to the lead terminal 4_{V}. The switching device 1f and the diode 2f are mounted on a die pad portion of the lead terminal 4_{W}. A collector of the switching device 1f and a cathode of the diode 2f are connected to the lead terminal 4_{W}.

An emitter of the switching device 1a, an anode of the diode 2a, and the lead terminal 4_{U} are wire-connected in this order. An emitter of the switching device 1b, an anode of the diode 2b, and the lead terminal 4_{V} are wire-connected in this order. An emitter of the switching device 1c, an anode of the diode 2c, and the lead terminal 4_{W} are wire-connected in this order. An emitter of the switching device 1d, an anode of the diode 2d, and the lead terminal 4_{NU} are wire-connected in this order. An emitter of the switching device 1e, an anode of the diode 2e, and the lead terminal 4_{NV} are wire-connected in this order. An emitter of the switching device 1f, an anode of the diode 2f, and the lead terminal 4_{NW} are wire-connected in this order.

The first and second control semiconductor devices 3a and 3b are mounted on a die pad portion of the lead terminal 4_{VNC}. Terminals UOUT, VOUT, and WOUT of the first control semiconductor device 3a are connected to gates of the switching devices 1a, 1b, and 1c, respectively. Terminals UOUT, VOUT, and WOUT of the second control semiconductor device 3b are connected to gates of the switching devices 1d, 1e, and 1f, respectively. The terminals UOUT, VOUT, and WOUT are terminals that output drive signals for the switching devices. Terminals VUS, VVS, and VWS of the first control semiconductor device 3a are wire-connected to emitter electrodes of the switching devices 1a, 1b, and 1c, respectively, and are connected to the lead terminals 4_{U}, 4_{V}, and 4_{W}.

Terminals VCC, VUB, UP, VVB, VP, VWB, WP, and COM of the first control semiconductor device 3a are wire-connected to the lead terminals 4_{VP1}, 4_{VUFB}, 4_{UP}, 4_{VVFB}, 4_{VP}, 4_{VWFB}, 4_{WP}, and 4_{VNC}, respectively. The terminal VCC is a power supply terminal. The terminals VUB, VVB, and VWB are P-side drive power supply voltage terminals. The terminals UP, VP, and WP are input terminals that input a control signal from an external logic circuit (not illustrated). The terminal COM is a ground terminal.

Terminals VCC, UN, VN, WN, Fo, CFo, VNC, and CIN of the second control semiconductor device 3b are wire-connected to the lead terminals 4_{VN1}, 4_{UN}, 4_{VN}, 4_{WN}, 4_{Fo}, 4_{CFo}, 4_{VNC}, and 4_{CIN}, respectively. The terminals UN, VN, and WN are input terminals that input a control signal from an external logic circuit. The terminal Fo is an error signal output terminal that outputs an error signal. The terminal VNC is a grounded ground terminal. When a signal is input to the terminal CIN at the time of short-circuit detection, the second control semiconductor device 3b shuts off the switching devices of the lower arm.

The diode 2g is mounted on the lead terminal 4_{VUFB}. A cathode of the diode 2g is connected to the lead terminal 4_{VUFB}. An anode of the diode 2g is wire-connected to the lead terminal 4_{VP1}. The diode 2h is mounted on the lead terminal 4_{VVFB}. A cathode of the diode 2h is connected to the lead terminal 4_{VVFB}. An anode of the diode 2h is wire-connected to the lead terminal 4_{VP1}. The diode 2i is mounted on the lead terminal 4_{VWFB}. A cathode of the diode 2i is connected to the lead terminal 4_{VWFB}. An anode of the diode 2i is wire-connected to the lead terminal 4_{VP1}. A capacitance adjustment unit 5 is provided on the lead terminals 4_{CFo} and 4_{VNC}.

An insulating sheet 6 is attached to lower surfaces of the die pad portions of the lead terminals 4_{P}, 4_{U}, 4_{V}, and 4_{W} on which the switching devices 1a to 1f and the diodes 2a to 2f are mounted. A molding resin 7 encapsulates the switching devices 1a to 1f, the diodes 2a to 2i, the first and second control semiconductor devices 3a and 3b, the capacitance adjustment unit 5, each lead terminal, and each wire. A tip of each lead terminal projects from the molding resin 7. However, a tip of the lead terminal 4_{CFo} does not project from the molding resin 7. The insulating sheet 6 is exposed from the molding resin 7 in the lower surface of the device. Heat of the switching devices 1a to 1f and the diodes 2a to 2f are dissipated via the insulating sheet 6. An opening 7a is provided in the molding resin 7, so that a part of the capacitance adjustment unit 5 is exposed from the molding resin 7.

The first control semiconductor device 3a controls the operations of the switching devices 1a, 1b, and 1c according to outputs from the terminals UOUT, VOUT, and WOUT, respectively. The terminals UOUT, VOUT, and WOUT of the second control semiconductor device 3b are connected to gates of the switching devices 1d, 1e, and 1f, respectively. The second control semiconductor device 3b controls the operations of the switching devices 1d, 1e, and 1f according to outputs from the terminals UOUT, VOUT, and WOUT, respectively.

The diodes 2g, 2h, and 2i are voltage boosting diodes used for charging external boot strap capacitors (not illustrated). Specifically, the boot strap capacitors are individually connected between the terminals VUB and VUS, between the terminals VVB and VVS, and between the terminals VWB and VWS of the first control semiconductor device 3a, so that a boot strap circuit is formed. The boot strap capacitor connected between the terminals VUB and VUS is connected in series with the diode 2g and the switching device 1d between the terminals VP1 and NU of the semiconductor device. When the switching device 1d is turned on by a signal from the terminal UOUT of the second control semiconductor device 3b, the boot strap capacitor is charged. The boot strap capacitor connected between the terminals VVB and VVS and the boot strap capacitor connected between the terminals VWB and VWS are likewise charged. These boot strap capacitors cover the power consumption of the first control semiconductor device 3a. When the voltage boosting diodes are mounted inside the device, it becomes unnecessary to mount the voltage boosting diodes outside of the device, making it possible to reduce a substrate area of the semiconductor device.

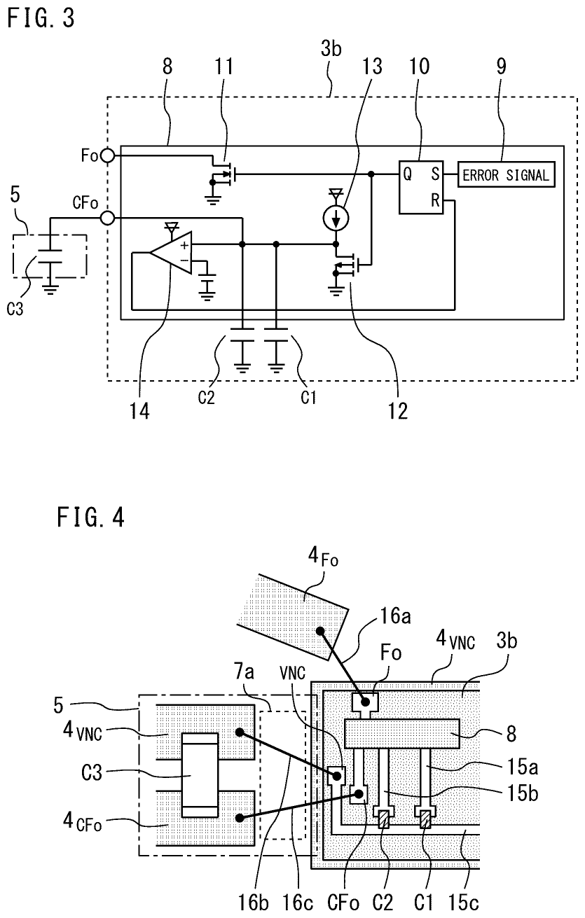

FIG. 3 is a circuit diagram illustrating a protection circuit of the second control semiconductor device according to the first embodiment. The second control semiconductor device 3b has a protection circuit 8 that outputs an error signal when an abnormality of the semiconductor device is detected such as an overcurrent, a reduction in control power supply voltage, and overheating. Capacitors C1 and C2 inside the second control semiconductor device 3b and a capacitor C3 outside the second control semiconductor device 3b are connected in parallel between the protection circuit 8 and a ground potential. The capacitor C3 is connected to the protection circuit 8 via the terminal CFo.

In the protection circuit 8, an error signal generated by an error signal generation unit 9 is output from the terminal Fo via an SR flip-flop 10 and an N-MOS transistor 11. Specifically, when the SR flip-flop 10 receives the error signal from an input S, an output Q is changed to an H level, and the N-MOS transistor 11 is turned on, so that the terminal Fo is changed to an L level. At this time, a P-MOS transistor 12 is turned off, and therefore, a current of a constant current source 13 charges the capacitors C1, C2, and C3. When the voltage of the charged capacitors C1, C2, and C3 exceeds a threshold of a comparator 14, a reset signal is input to an input R of the SR flip-flop 10, and the N-MOS transistor 11 is turned off, so that the terminal Fo is changed to an H level. At this time, the P-MOS transistor 12 is turned on, and therefore, the capacitors C1, C2, and C3 are discharged.

Therefore, the protection circuit 8 charges the capacitors C1, C2, and C3 while the error signal is output, and when the voltage of the charged capacitors C1, C2, and C3 exceeds the threshold, the output of the error signal is stopped, so that the capacitors C1, C2, and C3 are discharged. The larger the total capacitance value of the capacitors C1, C2, and C3 is, the longer the time until the voltage of the charged capacitors C1, C2, and C3 reaches the threshold of the comparator 14 is, which prolongs the output time of the error signal. To adjust the output time of the error signal, it is necessary to adjust the capacitance value of capacitance connected to the protection circuit 8.

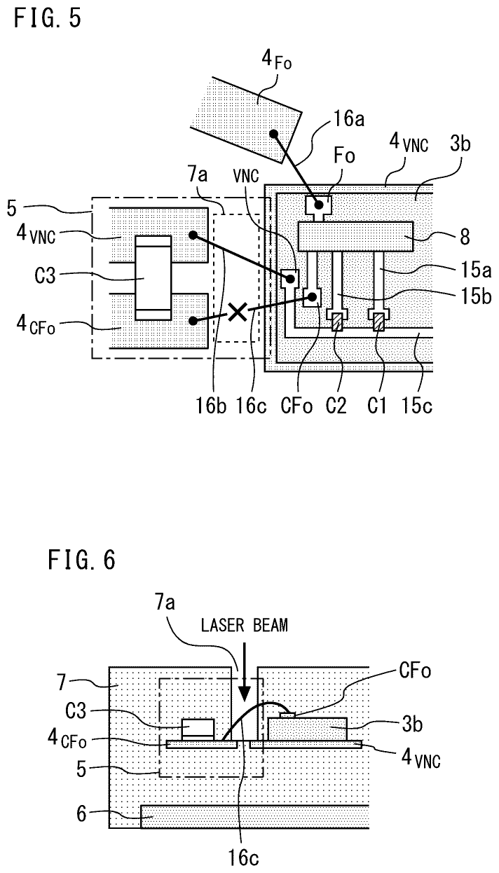

FIGS. 4 and 5 are top views illustrating the capacitance adjustment unit according to the first embodiment. FIG. 6 is a cross-sectional view illustrating the capacitance adjustment unit according to the first embodiment. In the second control semiconductor device 3b, the protection circuit 8 is connected to the terminal Fo and the terminal CFo. The protection circuit 8 is connected to one end of each of the capacitors C1 and C2 respectively via wirings 15a and 15b. The other end of each of the capacitors C1 and C2 and the terminal VNC are connected to a wiring 15c of the ground potential. The terminal Fo is connected to the lead terminal 4_{Fo} by a wire 16a. The wirings 15a, 15b, and 15c are, for example, aluminum wirings.

The capacitor C3 which is a chip capacitor is connected between the lead terminal 4_{VNC} and the lead terminal 4_{CFo}. The terminal VNC is connected to the lead terminal 4_{VNC} by a wire 16b. The terminal CFo is connected to the lead terminal 4_{CFo} by a wire 16c. That is, the protection circuit 8 is connected to the capacitor C3 via the wire 16c. The capacitor C3 and the wires 16b and 16c are included in the capacitance adjustment unit 5.

The wires 16b and 16c are exposed from the molding resin 7 through the opening 7a. Therefore, as illustrated in FIGS. 5 and 6, the wire 16c can be cut by laser trimming from the outside. Alternatively, the wire may be cut by a cutting tool such as scissors. Thus, the connection between the protection circuit 8 and the capacitor C3 is cut off, so that the capacitance value of the capacitance connected to the protection circuit 8 is reduced. That is, in order to increase the capacitance value of the capacitance connected to the protection circuit 8, the wire is not cut, and in order to reduce the capacitance value, the wire is cut so that the capacitor C3 is not connected in parallel to the capacitance.

As described above, in the present embodiment, the capacitance value of the capacitance connected to the protection circuit 8 can be adjusted depending on whether the wire 16c exposed from the molding resin 7 is cut from the outside. In addition, it is not necessary to house the capacitor in the opening 7a of the molding resin 7, which does not lead to an increase in the number of external terminals. As a result, the output period of the error signal can be externally adjusted without increasing the number of external terminals. In addition, it is not necessary to add the capacitor for adjusting the output period of the error signal in the vicinity of the device, which makes it possible to also reduce an area of the periphery of the semiconductor device. In order to mount, on the protection circuit 8, the capacitance value larger than the capacitance value in the second control semiconductor device 3b, the external capacitor C3 is used as in the present embodiment.

### Second Embodiment

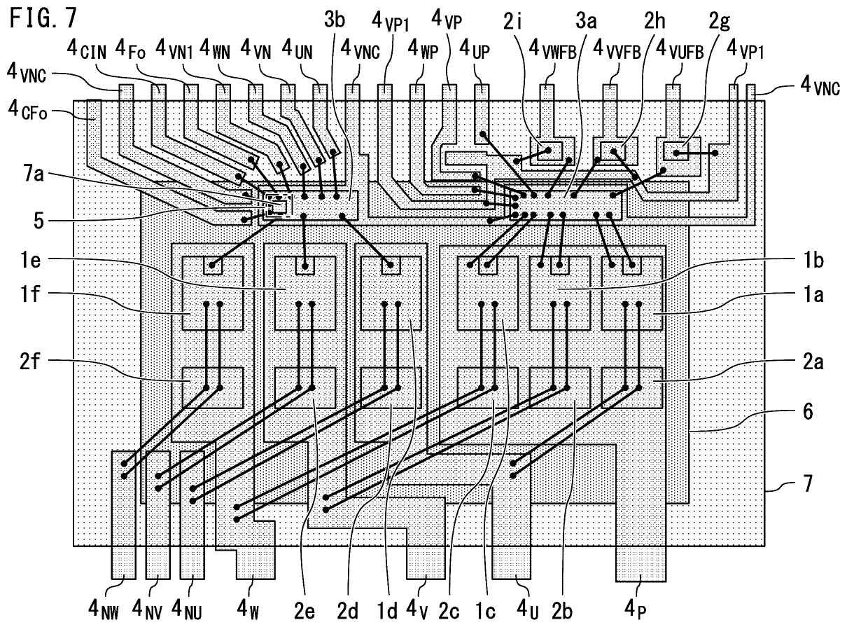

FIG. 7 is a plan view illustrating a semiconductor device according to a second embodiment. A capacitance adjustment unit 5 is built-in a second control semiconductor device 3b.

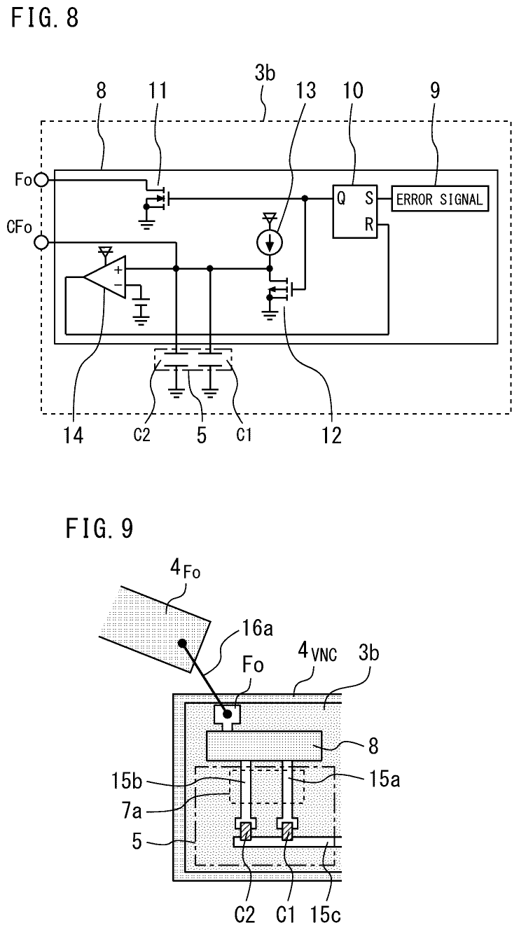

FIG. 8 is a circuit diagram illustrating a protection circuit of the second control semiconductor device according to the second embodiment. A capacitor C3 is not provided outside the second control semiconductor device 3b, and capacitors C1 and C2 inside the second control semiconductor device 3b are included in a capacitance adjustment unit 5.

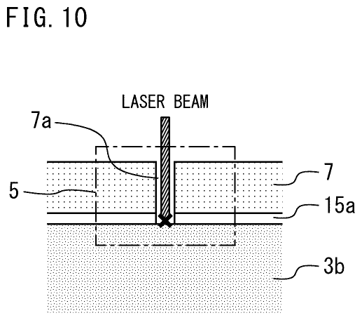

FIG. 9 is a top view illustrating the capacitance adjustment unit according to the second embodiment. FIG. 10 is a cross-sectional view illustrating the capacitance adjustment unit according to the second embodiment. The capacitors C1 and C2 connected in parallel to each other provide capacitance of the capacitance adjustment unit 5. Wirings 15a and 15b connect between the capacitor C1 and the protection circuit 8 and between the capacitor C2 and the protection circuit 8, respectively.

A part of the wirings 15a and 15b is exposed from a molding resin 7 through the opening 7a. Therefore, as illustrated in FIG. 10, one or both of the wirings 15a and 15b can be cut by laser trimming from the outside. Thus, the connection between the protection circuit 8 and the capacitors C1 and C2 is cut off, so that the capacitance value of the capacitance connected to the protection circuit 8 is reduced. That is, the capacitance value of the capacitance connected to the protection circuit 8 can be adjusted depending on whether the wirings 15a and 15b exposed from the molding resin 7 is cut from the outside. This makes it possible to externally adjust the output period of the error signal without increasing the number of external terminals in the same manner as in the first embodiment. Furthermore, this makes it possible to finely adjust the capacitance value by selecting whether the connection between a plurality of capacitors C1 and C2 connected in parallel to each other is cut off.

### Third Embodiment

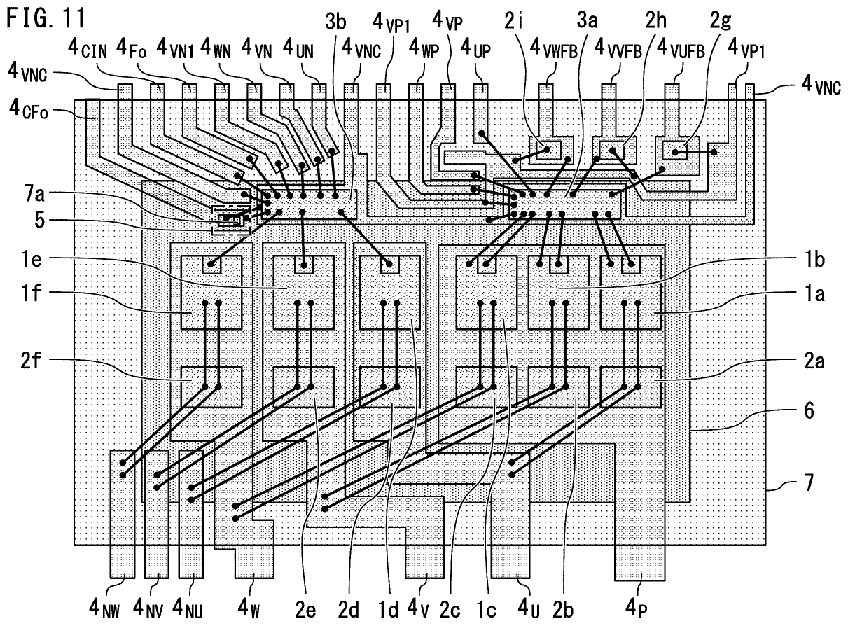

FIG. 11 is a plan view illustrating a semiconductor device according to a third embodiment. A capacitance adjustment unit 5 is provided on a lead terminal 4_{CFo} outside the second control semiconductor device 3b.

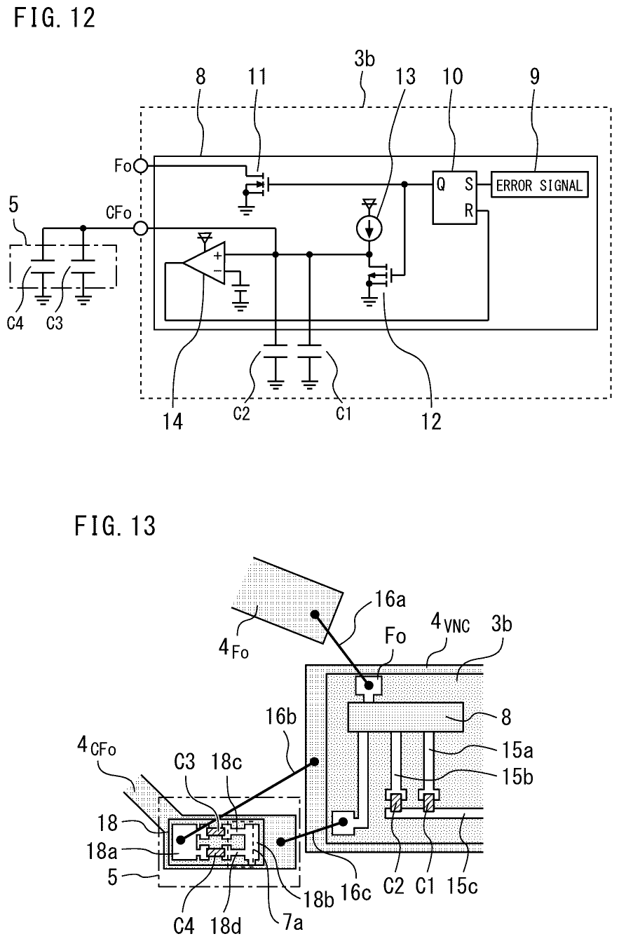

FIG. 12 is a circuit diagram illustrating a protection circuit of the second control semiconductor device according to the third embodiment. Capacitors C1 and C2 inside the second control semiconductor device 3b and capacitors C3 and C4 outside the second control semiconductor device 3b are connected in parallel between a protection circuit 8 and a ground potential. The capacitors C3 and C4 are connected to the protection circuit 8 via a terminal CFo.

FIG. 13 is a top view illustrating the capacitance adjustment unit according to the third embodiment. As the capacitance adjustment unit 5, a semiconductor chip 18 is provided on the lead terminal 4_{CFo}. Electrodes 18a and 18b and wirings 18c and 18d are provided on an upper surface of the semiconductor chip 18. The electrodes 18a and 18b and the wirings 18c and 18d are made of, for example, aluminum.

The electrode 18a is connected to the lead terminal 4_{VNC} of a ground potential by a wire 16b. The electrode 18b is connected to a lower electrode of the semiconductor chip 18 through a through hole. The lower electrode is joined to the lead terminal 4_{CFo} by means of soldering or the like. The lead terminal 4_{CFo} is connected to the terminal CFo of the second control semiconductor device 3b by a wire 16c. One end of each of the capacitors C3 and C4 is connected to the electrode 18a, and the other end of each of the capacitors C3 and C4 is connected to the electrode 18b via the wirings 18c and 18d, respectively.

A part of the wirings 18c and 18d is exposed from a molding resin 7 through the opening 7a. Therefore, one or both of the wirings 18c and 18d can be cut by laser trimming from the outside. The capacitance value of the capacitance connected to the protection circuit 8 can be adjusted depending on whether the wirings 18c and 18d exposed from the molding resin 7 is cut from the outside. This makes it possible to externally adjust the output period of the error signal without increasing the number of external terminals in the same manner as in the first embodiment. Furthermore, this makes it possible to finely adjust the capacitance value by selecting whether the connection between a plurality of capacitors C3 and C4 connected in parallel to each other is cut off.

### Fourth Embodiment

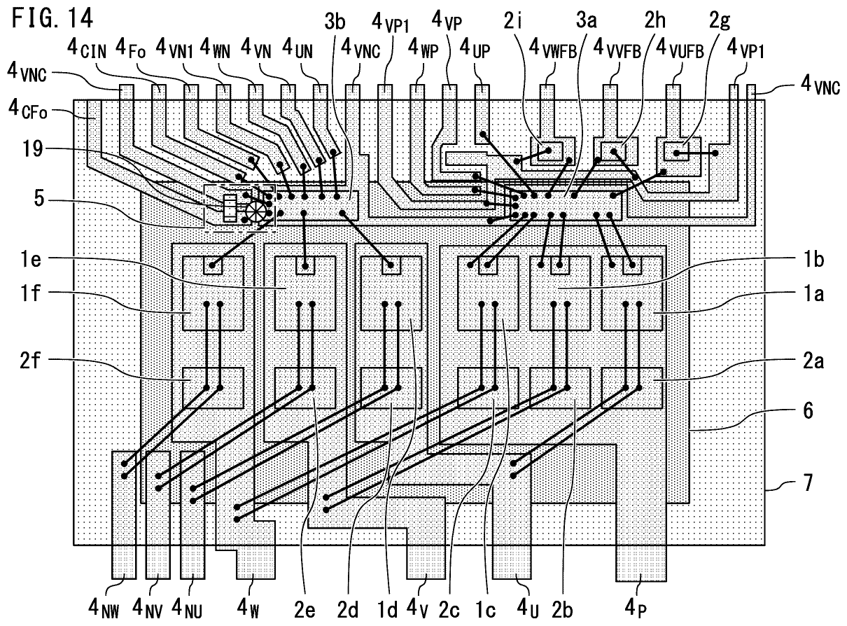

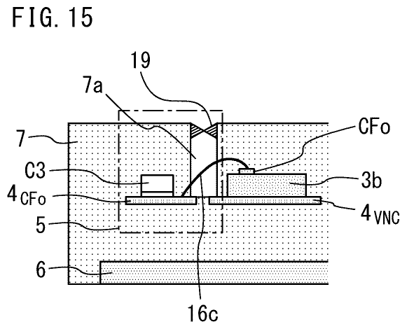

FIG. 14 is a plan view illustrating a semiconductor device according to a fourth embodiment. FIG. 15 is a cross-sectional view illustrating the capacitance adjustment unit according to the fourth embodiment. A freely openable and closable lid 19 is provided to an opening 7a. Using the lid 19, an upper portion of a capacitance adjustment unit 5 can be opened only when the capacitance is adjusted, and the opening 7a can be closed except when the capacitance is adjusted. This makes it possible to prevent foreign matters from entering from outside of the device, so that the reliability of the semiconductor device can be improved. The other configurations and effects are the same as those of the first embodiment.

### Fifth Embodiment

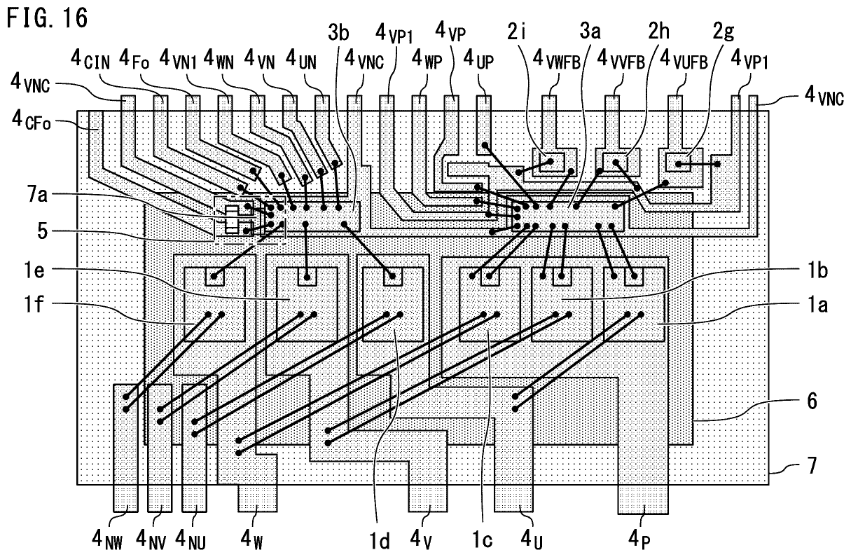

FIG. 16 is a plan view illustrating a semiconductor device according to a fifth embodiment. Each of switching devices 1a to 1f includes a transistor and a freewheel diode as one chip, and is, for example, a reverse conductive IGBT (RC-IGBT) including an IGBT and a freewheel diode as one chip. This makes it possible to omit the diodes 2a to 2f to miniaturize the semiconductor device, which leads to a reduction in substrate area of the semiconductor device.

The other configurations and effects are the same as those of the first embodiment.

The switching devices 1a to 1f and the diodes 2a to 2f are not limited to devices formed of silicon, but instead may be formed of a wide-bandgap semiconductor having a bandgap wider than that of silicon. The wide-bandgap semiconductor is, for example, a silicon carbide, a gallium-nitride-based material, or diamond. A semiconductor chip formed of such a wide-bandgap semiconductor has a high voltage resistance and a high allowable current density, and thus can be miniaturized. The use of such a miniaturized semiconductor chip enables the miniaturization and high integration of the semiconductor device in which the semiconductor chip is incorporated. Further, since the semiconductor chip has a high heat resistance, a radiation fin of a heatsink can be miniaturized and a water-cooled part can be air-cooled, which leads to further miniaturization of the semiconductor device. Further, since the semiconductor chip has a low power loss and a high efficiency, a highly efficient semiconductor device can be achieved.

Although the preferred embodiments and the like have been described in detail above, the present disclosure is not limited to the above-described embodiments and the like, but the above-described embodiments and the like can be subjected to various modifications and replacements without departing from the scope described in the claims. Aspects of the present disclosure will be collectively described as supplementary notes.

### (Supplementary Note 1)

A semiconductor device comprising:
a switching device;
a control semiconductor device controlling the switching device;
a capacitance adjustment unit including a capacitor and a conductor; and
a molding resin encapsulating the switching device, the control semiconductor device and the capacitance adjustment unit,
wherein the control semiconductor device includes a protection circuit outputting an error signal when an abnormality of the semiconductor device is detected,
the protection circuit is connected to the capacitor via the conductor and charges the capacitor while the error signal is output,
when voltage of the charged capacitor exceeds a threshold, the protection circuit stops the output of the error signal and discharges the capacitor,
an opening is formed in the molding resin, and
the conductor of the capacitance adjustment unit is exposed from the molding resin through the opening.

### (Supplementary Note 2)

The semiconductor device according to Supplementary Note 1, wherein the capacitor includes a chip capacitor,
the conductor includes a wire connecting the chip capacitor and the protection circuit, and
the wire is exposed from the molding resin through the opening.

### (Supplementary Note 3)

The semiconductor device according to Supplementary Note 1, wherein the capacitor includes a plurality of capacitors connected in parallel to each other,
the conductor includes a plurality of wirings connecting the plurality of capacitors and the protection circuit respectively, and
the plurality of wirings are exposed from the molding resin through the opening.

### (Supplementary Note 4)

The semiconductor device according to Supplementary Note 3, wherein the capacitance adjustment unit is built-in the control semiconductor device.

### (Supplementary Note 5)

The semiconductor device according to Supplementary Note 3, wherein the capacitance adjustment unit is provided on a lead terminal outside the control semiconductor device.

### (Supplementary Note 6)

The semiconductor device according to any one of Supplementary Notes 1 to 5, further comprising a freely openable and closable lid provided to the opening.

### (Supplementary Note 7)

The semiconductor device according to any one of Supplementary Notes 1 to 6, wherein the switching device includes a transistor and a freewheel diode as one chip.

### (Supplementary Note 8)

The semiconductor device according to any one of Supplementary Notes 1 to 7, wherein the switching device is formed of a wide-bandgap semiconductor.

### REFERENCE SIGNS LIST

1a-1f switching device; 3b second control semiconductor device; 4CFo lead terminal; 5 capacitance adjustment unit; 7 molding resin; 7a opening; 8 protection circuit; 15a,15b,18c,18d wiring; 16b,16c wire; 19 lid; C1,C2,C3,C4 capacitor

Obviously many modifications and variations of the present disclosure are possible in the light of the above teachings. It is therefore to be understood that within the scope of the appended claims the invention may be practiced otherwise than as specifically described.

The entire disclosure of Japanese Patent Application No. 2025-004046, filed on Jan. 10, 2025 including specification, claims, drawings and summary, on which the convention priority of the present application is based, is incorporated herein by reference in its entirety.

1. A semiconductor device comprising:
a switching device;
a control semiconductor device controlling the switching device;
a capacitance adjustment unit including a capacitor and a conductor; and
a molding resin encapsulating the switching device, the control semiconductor device and the capacitance adjustment unit,
wherein the control semiconductor device includes a protection circuit outputting an error signal when an abnormality of the semiconductor device is detected,
the protection circuit is connected to the capacitor via the conductor and charges the capacitor while the error signal is output,
when voltage of the charged capacitor exceeds a threshold, the protection circuit stops the output of the error signal and discharges the capacitor,
an opening is formed in the molding resin, and
the conductor of the capacitance adjustment unit is exposed from the molding resin through the opening.

2. The semiconductor device according to claim 1, wherein the capacitor includes a chip capacitor,
the conductor includes a wire connecting the chip capacitor and the protection circuit, and
the wire is exposed from the molding resin through the opening.

3. The semiconductor device according to claim 1, wherein the capacitor includes a plurality of capacitors connected in parallel to each other,
the conductor includes a plurality of wirings connecting the plurality of capacitors and the protection circuit respectively, and
the plurality of wirings are exposed from the molding resin through the opening.

4. The semiconductor device according to claim 3, wherein the capacitance adjustment unit is built-in the control semiconductor device.

5. The semiconductor device according to claim 3, wherein the capacitance adjustment unit is provided on a lead terminal outside the control semiconductor device.

6. The semiconductor device according to claim 1, further comprising a freely openable and closable lid provided to the opening.

7. The semiconductor device according to claim 1, wherein the switching device includes a transistor and a freewheel diode as one chip.

8. The semiconductor device according to claim 1, wherein the switching device is formed of a wide-bandgap semiconductor.
